(19) United States
(12) Patent Application Publication
(10) Pub. No.: US 2009/0289821 A1
(43) Pub. Date: Nov. 26, 2009

(54) PIPELINE ANALOG-TO-DIGITAL CONVERTER HAVING OPERATIONAL AMPLIFIER SHARED BY SAMPLE AND HOLD CIRCUIT AND LEADING MULTIPLYING DIGITAL-TO-ANALOG CONVERTER

(76) Inventors: Hung-Sung Li, Hsinchu County (TW); Ya-Lun Yang, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/126,934

(22) Filed: May 26, 2008

(51) Int. Cl. H03M 1/12; H03M 1/00

(52) U.S. Cl. 341/110; 341/122; 341/155

(57) ABSTRACT

A pipeline analog-to-digital converter includes a sample and hold circuit; a plurality of multiplying digital-to-analog converters having a leading MDAC coupled to the sample and hold circuit; and an operational amplifier, shared by the sample and hold circuit and the leading MDAC. The shared operational amplifier configured to be used by the sample and hold circuit when the sample and hold circuit enters a hold phase and used by the leading MDAC when the sample and hold circuit enters a sample phase can greatly reduce the power consumption of the pipeline ADC.

### BACKGROUND OF THE INVENTION

The present invention relates to a pipeline analog-to-digital converter (ADC), and more particularly, to a pipeline ADC having an operational amplifier shared by a sample and hold circuit and a leading multiplying digital-to-analog converter.

Pipeline ADC architectures are commonly employed in high speed and high-resolution analog-to-digital converters. Please refer to FIG. 1. FIG. 1 is a simplified block diagram illustrating a typical pipeline ADC 100. As shown in FIG. 1, the pipeline ADC 100 comprises a sample and hold (S/H) circuit 110, a plurality of multiplying digital-to-analog converters (MDACs) 1201, 120_2, . . . , 120_N and a digital circuit 130. The sample and hold circuit 110 is coupled to the leading MDAC 120_1. The plurality of MDACs 1201, 120_2, . . . , 120_N are connected in series and are coupled to the digital circuit 130. An analog input signal Sai is sampled and held by the sample and hold circuit 110 to generate a first analog input signal Sin1. Next, the first analog input signal Sin1 is processed by the MDAC 120_1 in order to generate a first digital signal Sout1 outputted to the digital circuit 130 and also to generate a second analog input signal Sin2 outputted to the subsequent MDAC 120_2. The second analog input signal Sin2 is then processed by the MDAC 120_2 in order to generate a second digital signal Sout2 outputted to the digital circuit 130 and also to generate a third analog input signal Sin3 outputted to the subsequent MDAC. Since the operations of the remaining MDACs are the same as described above, further description is omitted for brevity. After a plurality of digital signals Sout1, Sout2, . . . , SoutN have been generated and outputted to the digital circuit 130, the digital circuit 130 combines these digital signals to generate a digital output signal Sdo, which is the digitization result of the analog input signal Sai.

Please refer to FIG. 2. FIG. 2 is a simplified diagram illustrating a circuit structure of the leading MDAC 120_1 shown in FIG. 1. The MDAC 120_1 comprises an analog-to-digital converter 122, a digital-to-analog converter 124, an adder 126 and an amplifier 128. Because the circuit structures of other MDACs 120_2, . . . , 120_N are similar to that of the MDAC 120_1, only the detailed structure of the MDAC 120_1 is shown in FIG. 2 for simplicity. Additionally, since the detailed operation of the MDAC 120_1 is well known to those skilled in the art, further description is omitted here for the sake of brevity.

In typical pipeline ADC structures, the sample and hold circuit 110 and the plurality of MDACs 120_1, 120_2, . . . , 120_N each have one operational amplifier implemented therein. In other pipeline ADC structures, two of the plurality of MDACs 120_1, 120_2, . . . , 120_N may share a common operational amplifier for reducing circuit area and power consumption; for example, the MDAC 120_1 and the MDAC 120_2 may share one operational amplifier (e.g. the operational amplifier 128 shown in FIG. 2), and the MDAC 120_3 and the MDAC 120_4 may share another operational amplifier. However, there are no pipeline ADC structures whose sample and hold circuit 110 and leading MDAC 120_1 share a common operational amplifier. In general, the operational amplifier (not shown) in the sample and hold circuit 110 and the operational amplifier 128 in the leading MDAC 120_1 have the most power consumption in the pipeline ADC 100; therefore, if the sample and hold circuit 110 and the first stage MDAC 120_1 can share a common operational amplifier, the power consumption of the pipeline ADC 100 can be greatly reduced.

### SUMMARY OF THE INVENTION

It is therefore one of the objectives of the present invention to provide a pipeline analog-to-digital converter capable of sharing an operational amplifier between a sample and hold circuit and a leading MDAC, to solve the above-mentioned problem.

According to an exemplary embodiment of the claimed invention, a pipeline analog-to-digital converter (pipeline ADC) is disclosed. The pipeline ADC comprises a sample and hold circuit, a plurality of multiplying digital-to-analog converters (MDACs) and an operational amplifier. The plurality of MDACs have a leading MDAC coupled to the sample and hold circuit, and the operational amplifier is shared by the sample and hold circuit and the leading MDAC.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified block diagram illustrating a typical pipeline ADC.

FIG. 2 is a simplified diagram illustrating a circuit structure of a leading MDAC shown in FIG. 1.

FIG. 3 is a simplified block diagram illustrating a pipeline ADC according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

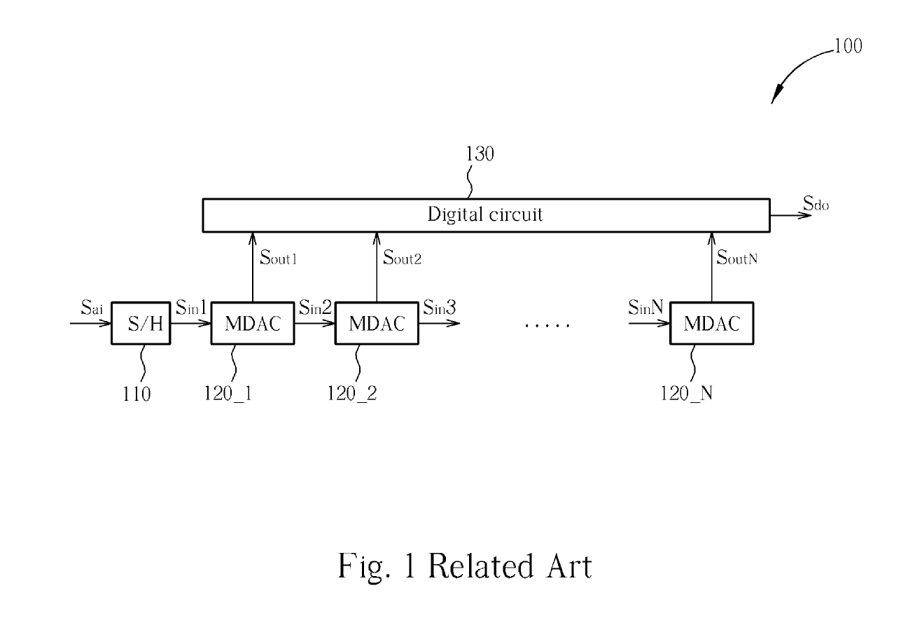

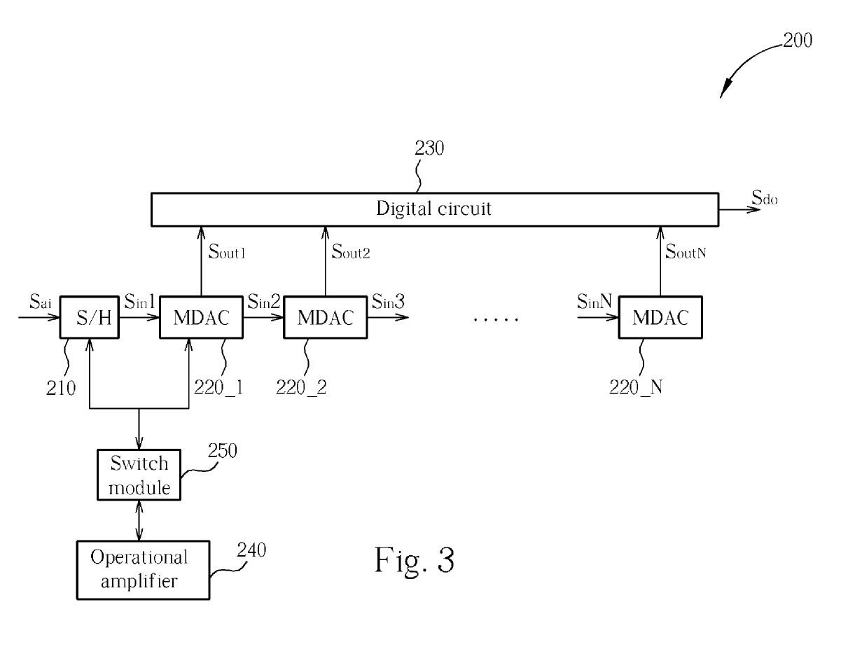

Please refer to FIG. 3. FIG. 3 is a simplified block diagram illustrating a pipeline analog-to-digital converter 200 (pipeline ADC) according to an embodiment of the present invention. As shown in FIG. 3, the pipeline ADC 200 comprises a sample and hold circuit 210, a plurality of multiplying digital-to-analog converters (MDACs) 220_1-220_N, a digital circuit 230, an operational amplifier 240 and a switch module 250. The plurality of MDACs are cascaded in series and have a leading MDAC 220_1 that is coupled to the sample and hold circuit 210, and the operational amplifier 240 is shared by the sample and hold circuit 210 and the leading MDAC 220_1. The switch module 250 is used for selectively coupling the operational amplifier 240 to the sample and hold circuit 210 or the leading MDAC 220_1 in each clock cycle of the pipeline ADC 200. Further description of the operation of the pipeline ADC 200 shown in FIG. 3 is detailed below. Because operations and functions of the elements of the multimedia pipeline ADC 200 shown in FIG. 3 are similar to elements with the same name in the pipeline ADC 100 shown in FIG. 1, further descriptions are not detailed here for the sake of brevity. It should be noted that the following exemplary embodiment is for illustrative purposes only and is not meant to be taken as limitations of the present invention.

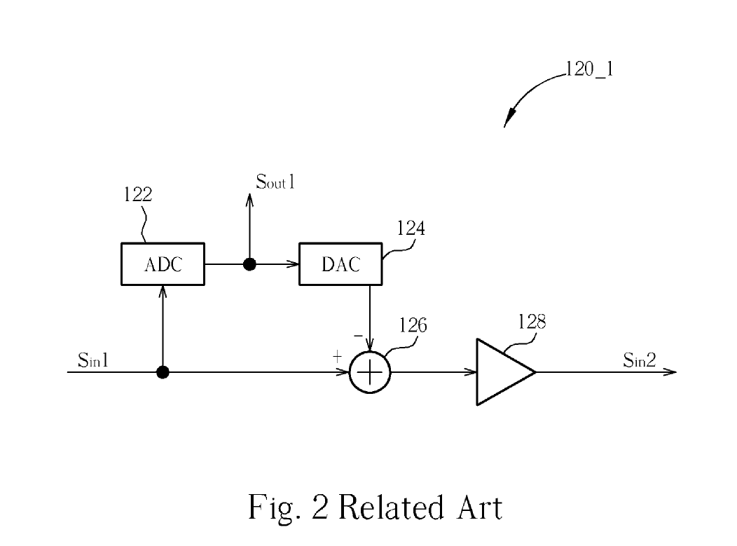

In a first period of a clock cycle, the operational amplifier 240 is coupled to the sample and hold circuit 210 via the switch module 250; and in a second period of the clock cycle, the operational amplifier 240 is coupled to the leading MDAC 220_1 via the switch module 250. In this embodiment, the first period corresponds to a hold phase of the sample and hold circuit 210, and the second period corresponds to a sample phase of the sample and hold circuit 210; however, this is merely for illustrative purposes, and is not meant to be a limitation of the present invention. In the first period of the clock cycle (e.g. the hold phase of the sample and hold circuit 210), the sample and hold circuit 210 needs to use the operational amplifier 240 for its intended operation, while there is no need for the leading MDAC 220_1 to use the operational amplifier 240, so the switch module 250 is configured to couple the operational amplifier 240 to the sample and hold circuit 210 so as to allow the operational amplifier 240 to be used by the sample and hold circuit 210. On the other hand, in the second period of the clock cycle (e.g. the sample phase of the sample and hold circuit 210), there is no need for the sample and hold circuit 210 to use the operational amplifier 240, while the leading MDAC 220_1 needs the operational amplifier 240 for its intended functionality, so the switch module 250 couples the operational amplifier 240 to the leading MDAC 220_1 instead so as to allow the operational amplifier 240 to serve as a residue amplifier of the leading MDAC 220_1 (e.g. the operational amplifier 128 shown in FIG. 2). Therefore, as both the sample and hold circuit 210 and the leading MDAC 220_1 do not request the shared operational amplifier 240 at the same time, the sample and hold circuit 210 and the leading MDAC 220_1 can share the single operational amplifier 240 in each clock cycle of the pipeline ADC 200.

In addition, since the feedback factor of the operational amplifier 240 will be different depending on the operational amplifier 240 used by the sample and hold circuit 210 or by the leading MDAC 220_1, it is necessary to modify the feedback factor of the operational amplifier 240. For example, the feedback factor of the operational amplifier 240 can be modified by adjusting the compensation capacitor or DC gain of the operational amplifier 240. After reading the above-mentioned description concerning how to adjust the feedback factor of the operational amplifier 240, a corresponding method for modifying the feedback factor of the operational amplifier 240 should be readily appreciated by those skilled in the art, so further description is omitted here for the sake of brevity.

Compared to the related art, the present invention can save the pipeline ADC 200 one operational amplifier through the shared operational amplifier 240 configured to be used by the sample and hold circuit 210 when the sample and hold circuit 210 enters a hold phase and used by the leading MDAC 220_1 when the sample and hold circuit 210 enters a sample phase, thereby greatly decreasing the total power consumption of the pipeline ADC 200.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pipeline analog-to-digital converter (pipeline ADC), comprising:
a sample and hold circuit;
a plurality of multiplying digital-to-analog converters (MDACs), having a leading MDAC coupled to the sample and hold circuit; and
an operational amplifier, shared by the sample and hold circuit and the leading MDAC.

2. The pipeline analog-to-digital converter of claim 1, further comprising a switch module for selectively coupling the operational amplifier to the sample and hold circuit or the leading MDAC in each clock cycle of the pipeline analog-to-digital converter.

3. The pipeline analog-to-digital converter of claim 2, wherein in a first period of the clock cycle, the operational amplifier is coupled to the sample and hold circuit; and in a second period of the clock cycle, the operational amplifier is coupled to the leading MDAC.

4. The pipeline analog-to-digital converter of claim 3, wherein the first period corresponds to a hold phase of the sample and hold circuit, and the second period corresponds to a sample phase of the sample and hold circuit.
